(19) United States
(12) Patent Application Publication
(10) Pub. No.: US 2026/0129996 A1
(43) Pub. Date: May 7, 2026

(54) CHIP PACKAGE AND MANUFACTURING METHOD THEREOF

(71) Applicant: XINTEC INC., Taoyuan City (TW)

(72) Inventors: Yu-Ting HUANG, Taoyuan City (TW); Wei-Luen SUEN, Taoyuan City (TW); Po-Jung CHEN, Kouhu Township (TW)

(21) Appl. No.: 19/360,883

(22) Filed: Oct. 16, 2025

Related U.S. Application Data
(60) Provisional application No. 63/716,786, filed on Nov. 6, 2024.

(51) Int. Cl. H10F 39/00

(52) U.S. Cl. CPC H10F 39/811; H10F 39/024; H10F 39/804; H10F 39/805

(57) ABSTRACT

A chip package includes a semiconductor substrate, a bonding adhesive, a support element, a first protection layer, and a second protection layer. The top surface of the semiconductor substrate has a conductive pad and a sensing area, and the corner of the top surface of the semiconductor substrate has a groove. The bonding adhesive is located in the groove. The support element covers the bonding adhesive and the conductive pad, and surrounds the sensing area. The first protection layer is located on the bottom surface of the semiconductor substrate. The second protection layer covers the first protection layer, the sidewall of the semiconductor substrate, and the lateral surface of the bonding adhesive.

### CROSS-REFERENCE TO RELATED APPLICATION

This application claims priority to U.S. Provisional Application Ser. No. 63/716,786, filed Nov. 6, 2024, which is herein incorporated by reference.

### BACKGROUND

### Field of Invention

The present disclosure relates to a chip package and a manufacturing method of the chip package.

### Description of Related Art

Generally speaking, a chip package for image sensing includes a light-transmitting sheet and a semiconductor substrate having a sensing area. In addition, the chip package may further include a redistribution layer, solder balls, and a protection layer (e.g., green paint).

The protection layer of a traditional chip package is merely located on the bottom surface of the semiconductor substrate. For example, the protection layer may be patterned to form an opening, and then a ball implantation process may be performed. However, the semiconductor substrate has no structure to prevent stress transmission. Therefore, during the manufacture of the chip package, stress may be transmitted to the inside of the semiconductor substrate and cause damage. In addition, the sidewall of the semiconductor substrate is exposed, and thus moisture may enter the chip package from the edge of the semiconductor substrate, and noise light may also enter from the lateral side of the semiconductor substrate and the lateral side of the light-transmitting sheet. As a result, the yield and reliability of the chip package are not only difficult to improve, but also not conducive to the image sensing accuracy of the chip package.

### SUMMARY

According to some embodiments of the present disclosure, a chip package includes a semiconductor substrate, a bonding adhesive, a support element, a first protection layer, and a second protection layer. A top surface of the semiconductor substrate has a conductive pad and a sensing area, and a corner of the top surface has a groove. The bonding adhesive is located in the groove. The support element covers the bonding adhesive and the conductive pad and surrounds the sensing area. The first protection layer is located on a bottom surface of the semiconductor substrate. The second protection layer covers the first protection layer, a sidewall of the semiconductor substrate, and a lateral surface of the bonding adhesive.

In some embodiments, a corner of a bottom surface of the support element has a recess, and the second protection layer extends into the recess.

In some embodiments, the chip package further includes a light-transmitting sheet located on the support element and above the sensing area.

In some embodiments, the second protection layer further covers a sidewall of the support element, a sidewall of the light-transmitting sheet, and a top surface of the light-transmitting sheet.

In some embodiments, the second protection layer is in direct contact with the sidewall of the semiconductor substrate, the lateral surface of the bonding adhesive, the sidewall of the support element, the sidewall of the light-transmitting sheet, and the top surface of the light-transmitting sheet.

In some embodiments, the light-transmitting sheet further includes two anti-reflective layers respectively located on a top surface and a bottom surface of the light-transmitting sheet.

In some embodiments, the second protection layer extends to the anti-reflective layer on the top surface of the light-transmitting sheet.

In some embodiments, the second protection layer is in direct contact with the sidewall of the semiconductor substrate, the lateral surface of the bonding adhesive, and the support element.

In some embodiments, a material of the first protection layer is different from a material of the second protection layer, and a color of the first protection layer is different from a color of the second protection layer.

In some embodiments, the semiconductor substrate has a through hole, the conductive pad is located in the through hole, and the chip package further includes an isolation layer, a redistribution layer, and an under bump metal. The isolation layer is located on a wall surface of the through hole and the bottom surface of the semiconductor substrate. The redistribution layer is located on the conductive pad and the isolation layer. The under bump metal is located on the redistribution layer and the first protection layer.

In some embodiments, a material of the redistribution layer is copper, and a material of the under bump metal comprises copper, nickel, and gold.

In some embodiments, a portion of the under bump metal is located between the first protection layer and the second protection layer.

In some embodiments, the chip package further includes a conductive structure located on the under bump metal and surrounded by the second protection layer.

According to some embodiments of the present disclosure, a manufacturing method of a chip package includes forming a groove in a top surface of a semiconductor substrate, wherein the top surface of the semiconductor substrate has a conductive pad and a sensing area; using a bonding adhesive to adhere a support element to the top surface of the semiconductor substrate, wherein the bonding adhesive is located in the groove, and the support element covers the bonding adhesive and surrounds the sensing area; forming a first protection layer on a bottom surface of the semiconductor substrate; forming a scribe line in the semiconductor substrate and the support element, wherein the bonding adhesive is exposed through the scribe line; and forming a second protection layer in the scribe line and on the first protection layer such that the second protection layer covers the first protection layer, a sidewall of the semiconductor substrate, and a lateral surface of the bonding adhesive.

In some embodiments, the groove of the semiconductor substrate is formed by laser grooving.

In some embodiments, forming the scribe line in the semiconductor substrate and the support element is performed such that a corner of a bottom surface of the support element has a recess.

In some embodiments, forming the second protection layer in the scribe line and on the first protection layer is performed such the second protection layer extends into the recess of the support element.

In some embodiments, the manufacturing method of the chip package further includes disposing the support element on a bottom surface of a light-transmitting sheet.

In some embodiments, a top surface of the light-transmitting sheet is bonded to a carrier, and the manufacturing method of the chip package further includes cutting the second protection layer along the scribe line.

In some embodiments, forming the scribe line in the semiconductor substrate and the support element is performed such that the scribe line extends into the light-transmitting sheet.

In some embodiments, forming the second protection layer in the scribe line and on the first protection layer is performed such that the second protection layer extends into the light-transmitting sheet.

In some embodiments, the manufacturing method of the chip package further includes grinding a top surface of the light-transmitting sheet to expose a portion of the second protection layer; and forming another second protection layer on the top surface of the light-transmitting sheet and extending to said portion of the second protection layer.

In the aforementioned embodiments of the present disclosure, since the corner of the top surface of the semiconductor substrate has the groove, the bonding adhesive is located in the groove, and the support element covers the bonding adhesive and the conductive pad, the groove and the bonding adhesive in the groove can prevent stress from transmitting to the inside of the semiconductor substrate during the manufacture of the chip package to avoid damage. Moreover, the chip package has the first protection layer and the second protection layer, and the second protection layer covers the sidewall of the semiconductor substrate and the lateral surface of the bonding adhesive, thereby effectively preventing moisture from entering the chip package and preventing noise light from entering the lateral surface of the semiconductor substrate. As a result, the yield rate and the reliability of the chip package can be improved, and such a configuration is beneficial to the image sensing accuracy of the chip package.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a cross-sectional view of a chip package according to one embodiment of the present disclosure.

FIGS. 2 to 10 are cross-sectional views at intermediate stages of the manufacturing method of the chip package of FIG. 1.

FIG. 11 is a cross-sectional view of a chip package according to another embodiment of the present disclosure.

FIGS. 12 to 16 are cross-sectional views at intermediate stages of the manufacturing method of the chip package of FIG. 11.

FIGS. 17 to 19 are cross-sectional views of chip packages according to other embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

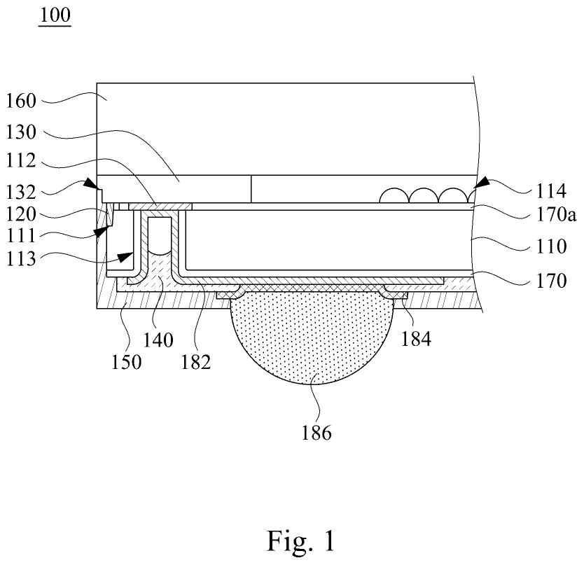

FIG. 1 is a cross-sectional view of a chip package 100 according to one embodiment of the present disclosure. As shown in FIG. 1, the chip package 100 includes a semiconductor substrate 110, a bonding adhesive 120, a support element 130, a first protection layer 140, and a second protection layer 150. The top surface of the semiconductor substrate 110 has a conductive pad 112 and a sensing area 114, and the corner of the top surface of the semiconductor substrate 110 has a groove 111. The semiconductor substrate 110 may be an image sensor, such as a complementary metal-oxide semiconductor (CMOS) image sensor. The sensing area 114 is an image sensing area. The bonding adhesive 120 is located in the groove 111 of the semiconductor substrate 110. In order to clarify the drawing, FIG. 1 merely shows the cross-sectional view of one side of the chip package 100. The support element 130 is a frame structure surrounding the sensing area 114, and covers the bonding adhesive 120 and the conductive pad 112. Moreover, the material of the support element 130 may be polymer. In this embodiment, the corner of the bottom surface of the support element 130 has a recess 132, and the second protection layer 150 extends into the recess 132 of the support element 130. The second protection layer 150 may be in direct contact with the sidewall of the semiconductor substrate 110, the lateral surface of the bonding adhesive 120, and the support element 130.

Furthermore, the first protection layer 140 is located on the bottom surface of the semiconductor substrate 110. The second protection layer 150 covers the first protection layer 140, the sidewall of the semiconductor substrate 110, the lateral surface of the bonding adhesive 120. The first protection layer 140 and the second protection layer 150 may be referred to as a composite passivation layer. The material of the first protection layer 140 is different from the material of the second protection layer 150, and the color of the first protection layer 140 is different from the color of the second protection layer 150. For example, the first protection layer 140 has the characteristics of non-hygroscopicity, low thermal expansion coefficient and heat resistance (such as heat resistance of 300° C.), and its material may include photoresist and polyimide (PI). The second protection layer 150 has the characteristics of light blocking and water blocking, and may be a black solder mask, such as a black paint.

Specifically, since the corner of the top surface of the semiconductor substrate 110 has the groove 111, the bonding adhesive 120 is located in the groove 111, and the support element 130 covers the bonding adhesive 120 and the conductive pad 112, the groove 111 and the bonding adhesive 120 in the groove 111 can prevent stress from transmitting to the inside of the semiconductor substrate 110 during the manufacture of the chip package 100 to avoid damage. Moreover, the chip package 100 has the first protection layer 140 and the second protection layer 150, and the second protection layer 150 covers the sidewall of the semiconductor substrate 110 and the lateral surface of the bonding adhesive 120, thereby effectively preventing moisture from entering the chip package 100 and preventing noise light from entering the lateral surface of the semiconductor substrate 110. As a result, the yield rate and the reliability of the chip package 100 can be improved, and such a configuration is beneficial to the image sensing accuracy of the chip package 100.

Additionally, in this embodiment, the chip package 100 further includes a light-transmitting sheet 160. The light-transmitting sheet 160 is located on the support element 130 and above the sensing area 114. In other words, the support element 130 is located between the light-transmitting sheet 160 and the semiconductor substrate 110. Moreover, the semiconductor substrate 110 has a through hole 113, and the conductive pad 112 is located in the through hole 113. In other words, the positon of the through hole 113 corresponds to the positon of the conductive pad 112. The chip package 100 further includes an isolation layer 170, a redistribution layer 182, and an under bump metal (UBM) 184. The isolation layer 170 is located on the wall surface of the through hole 113 and the bottom surface of the semiconductor substrate 110. The redistribution layer 182 is located on the conductive pad 112 and the isolation layer 170. The under bump metal 184 is located on the redistribution layer 182 and the first protection layer 140. The material of the redistribution layer 182 may be only copper (i.e., Cu only). The material of the under bump metal 184 may include copper, nickel, and gold, such as the under bump metal 184 including a copper layer, a nickel layer, and a gold layer from top to bottom. A portion of the under bump metal 184 is located between the first protection layer 140 and the second protection layer 150. The chip package 100 may further include a conductive structure 186. The conductive structure 186 is located on the under bump metal 184, and is surrounded by the second protection layer 150. In some embodiments, the conductive structure 186 may be solder ball.

It is to be noted that the connection relationships, the materials, and the advantages of the elements described above will not be repeated in the following description. In the following description, the manufacturing method of the chip package 100 will be explained.

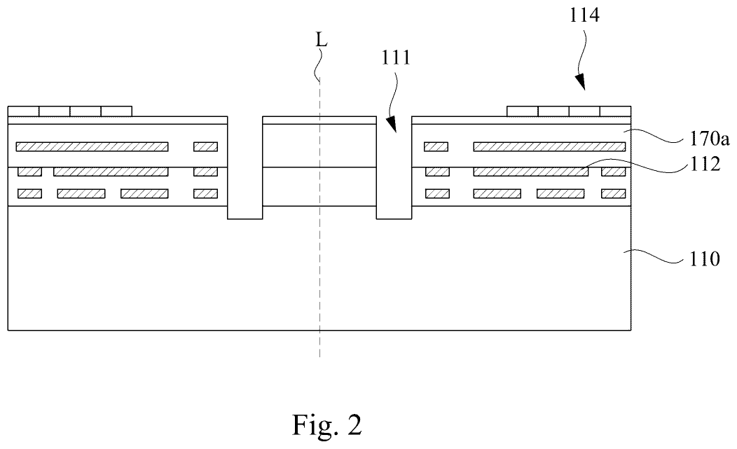

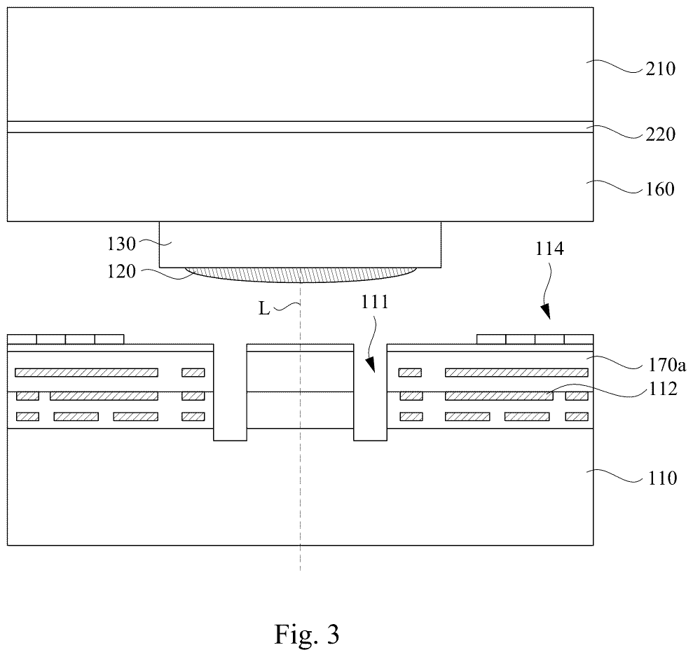

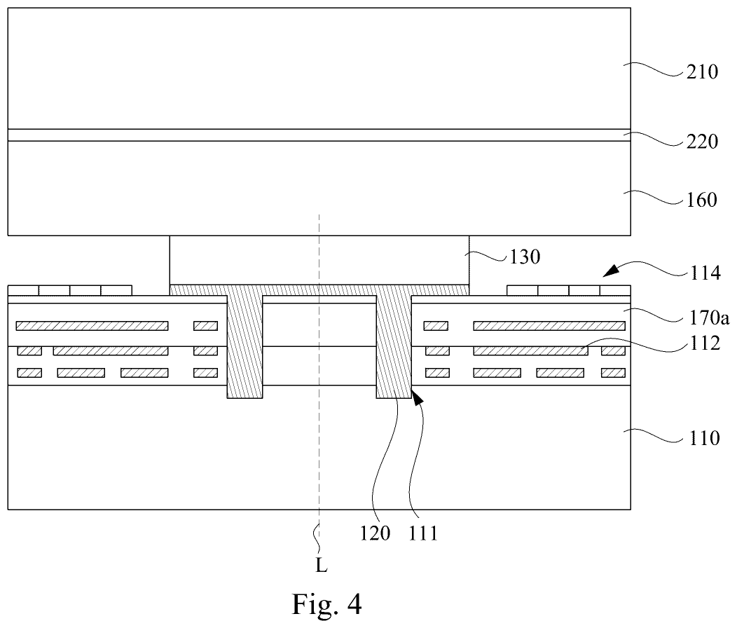

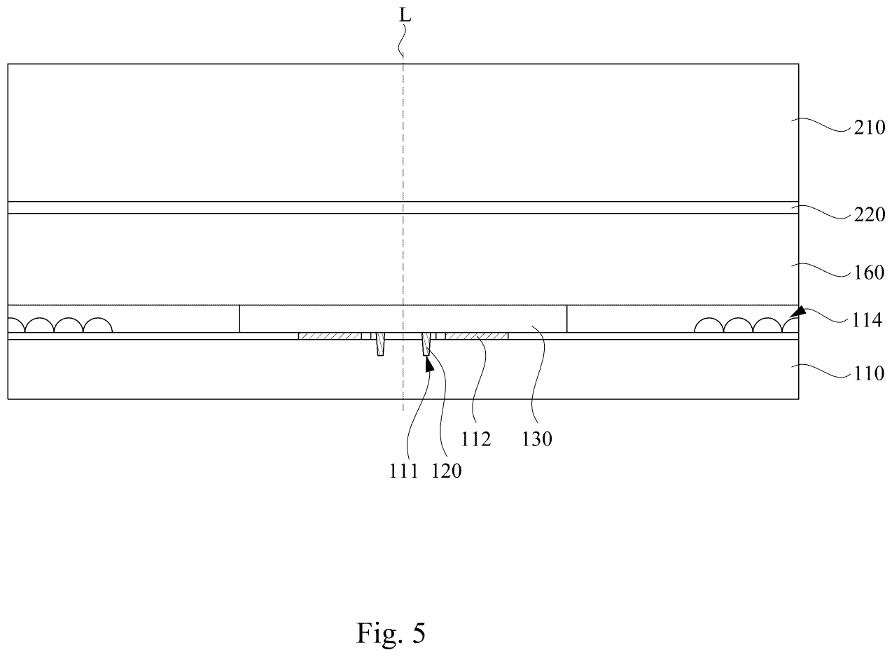

FIGS. 2 to 10 are cross-sectional views at intermediate stages of the manufacturing method of the chip package 100 of FIG. 1. A dashed line L is referred to as a predetermined position for performing a dicing process. FIGS. 2 to 4 are process steps of the semiconductor substrate 110 near the groove 111. FIGS. 5 to 10 are process steps after forming the bonding adhesive 120 of FIG. 4. As shown in FIG. 2, the top surface of the semiconductor substrate 110 has an isolation layer 170a, and the conductive pad 112 is located in the isolation layer 170a. The isolation layer 170a may include a multi-layer stack of low-k dielectric layers. The isolation layer 170a may further have a circuit layer and a device layer therein as deemed necessary by design. First of all, the groove 111 is formed in the top surface of the semiconductor substrate 110, in which the groove 111 of the semiconductor substrate 110 may be formed by laser grooving. As shown in FIG. 3, the support element 130 is disposed on the bottom surface of the light-transmitting sheet 160, and a temporary bonding layer 220 is used to bond the top surface of the light-transmitting sheet 160 to a carrier 210. The bonding adhesive 120 is coated on the bottom surface of the support element 130.

As shown in FIG. 4, thereafter, the bonding adhesive 120 is used to adhere the support element 130 to the top surface of the semiconductor substrate 110, such that the bonding adhesive 120 is located in the groove 111, and the support element 130 covers the bonding adhesive 120 and surrounds the sensing area 114.

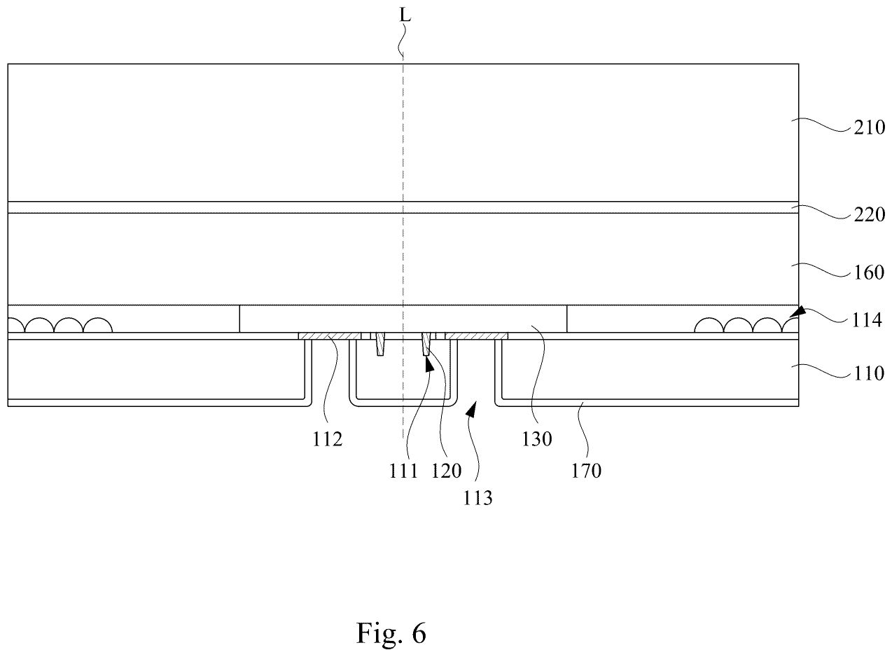

As shown in FIG. 5, the partially enlarged view near the bonding adhesive 120 and the groove 111 in FIG. 5 is the structure of FIG. 4. In the following description, the subsequent process will be explained based on the scale of FIG. 5. After the support element 130 is bonded to the semiconductor substrate 110, a grinding treatment may be performed on the bottom surface of the semiconductor substrate 110 to decrease the thickness of the semiconductor substrate 110. As shown in FIG. 6, the semiconductor substrate 110 may be etched to form the through hole 113, thereby exposing the conductive pad 112. Then, the isolation layer 170 may be formed on the bottom surface of the conductive pad 112, the wall surface of the through hole 113, and the bottom surface of the semiconductor substrate 110 by using chemical vapor deposition (CVD). The thickness of the isolation layer 170 may be, for example, 4 μm. Thereafter, the isolation layer 170 on the bottom surface of the conductive pad 112 is etched to expose the conductive pad 112, such that the structure of FIG. 6 can be obtained.

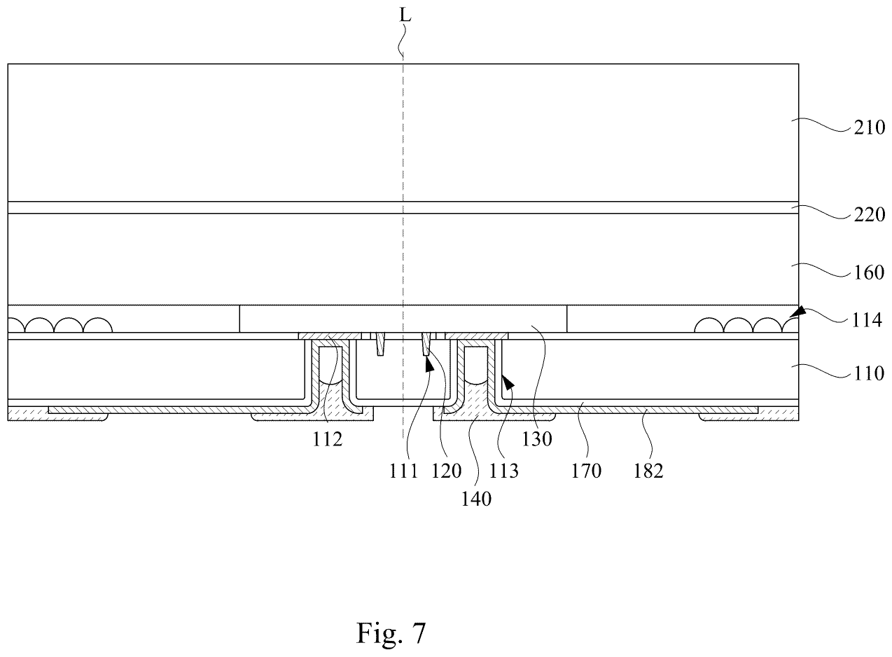

As shown in FIG. 7, thereafter, the redistribution layer 182 is formed on the bottom surface of the isolation layer 170 and the bottom surface of the conductive pad 112, in which the redistribution layer 182 may be, for example, a copper layer with a thickness of 3.5 μm. Thereafter, the first protection layer 140 is formed on the redistribution layer 182 and the isolation layer 170 that are on the bottom surface of the semiconductor substrate 110, and a portion of the first protection layer 140 extends into the through hole 113. The top surface of the first protection layer 140 in the through hole 113 is an arc profile.

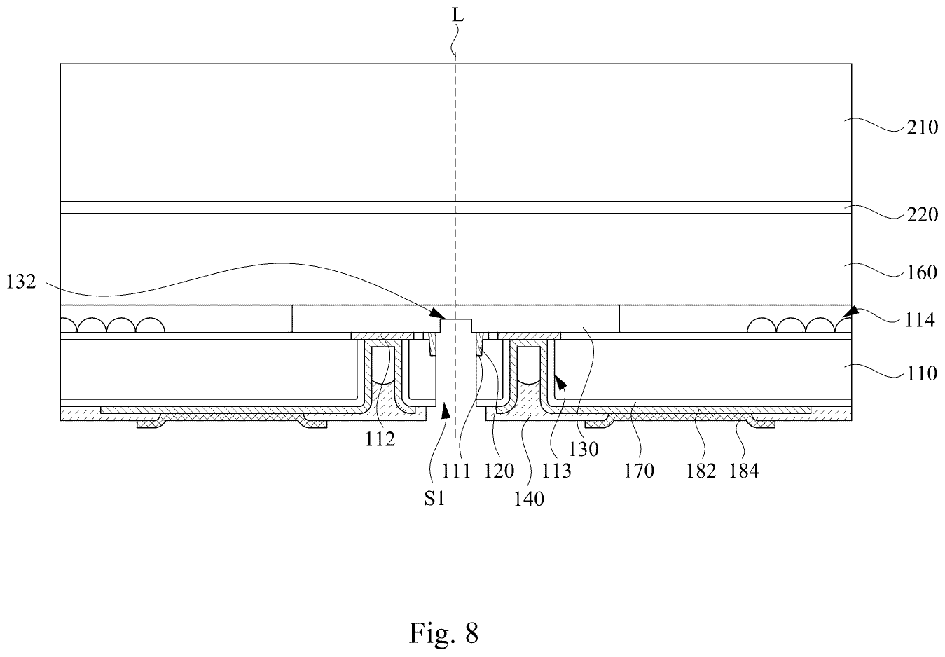

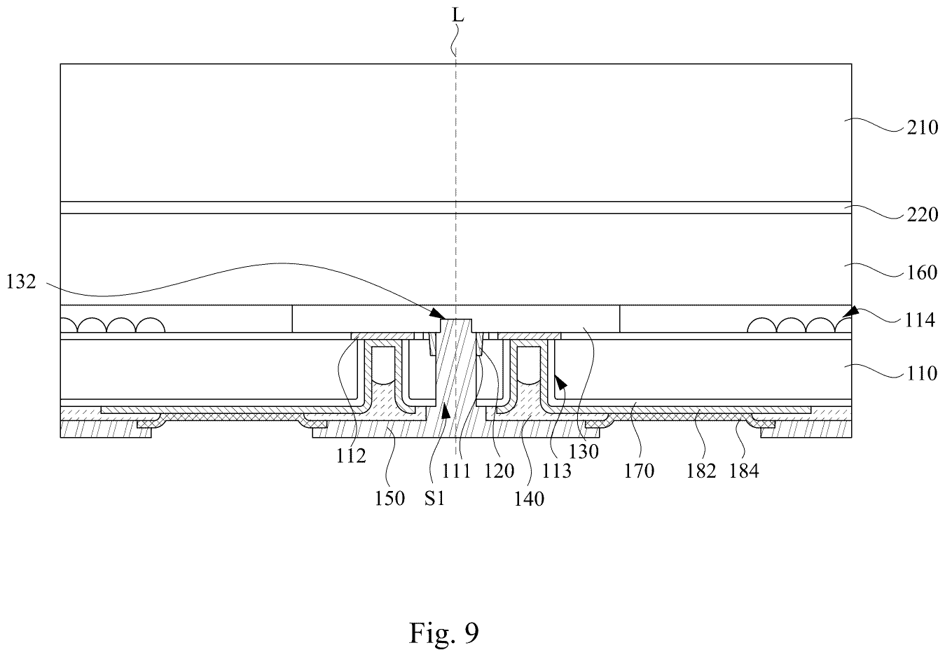

As shown in FIG. 8, thereafter, the under bump metal 184 is formed on the redistribution layer 182 not covered by the first protection layer 140, and a portion of the under bump metal 184 extends to the bottom surface of the first protection layer 140. Thereafter, a scribe line S1 is formed in the semiconductor substrate 110 and the support element 130, wherein the lateral surface of the bonding adhesive 120 can be exposed through the scribe line S1. The width of the scribe line S1 in the support element 130 may be smaller than that in the semiconductor substrate 110. In this step, the corner of the bottom surface of the support element 130 has the recess 132. As show in FIG. 9, thereafter, the second protection layer 150 is formed in the scribe line S1 and on the first protection layer 140, such that the second protection layer 150 covers the first protection layer 140, the sidewall of the semiconductor substrate 110, and the lateral surface of the bonding adhesive 120. In this step, the second protection layer 150 extends into the recess 132 of the support element 130.

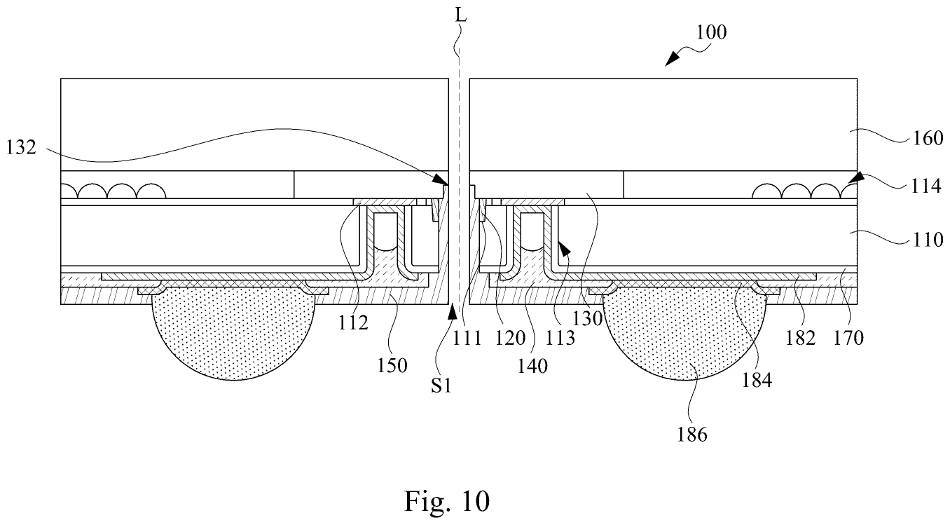

As shown in FIG. 9 and FIG. 10, after the formation of the second protection layer 150, the conductive structure 186 may be formed on the under bump metal 184, and then the carrier 210 and the temporary bonding layer 220 may be removed to expose the top surface of the light-transmitting sheet 160. Thereafter, the second protection layer 150, the support element 130, and the light-transmitting sheet 160 may be cut along the scribe line S1 (i.e., the position of the dashed line L), and thus the chip package 100 of FIG. 1 is obtained.

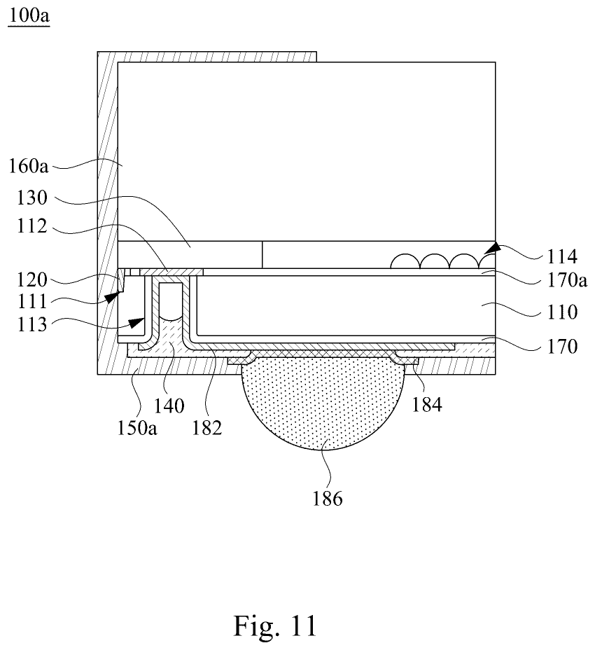

FIG. 11 is a cross-sectional view of a chip package 100a according to another embodiment of the present disclosure. The chip package 100a includes the semiconductor substrate 110, the bonding adhesive 120, the support element 130, the first protection layer 140, a second protection layer 150a, and a light-transmitting sheet 160a. The difference between this embodiment and the embodiment of FIG. 1 is that the second protection layer 150a further covers the sidewall of the support element 130, the sidewall of the light-transmitting sheet 160a, and the top surface of the light-transmitting sheet 160a. Moreover, the support element 130 of the chip package 100a has no aforementioned recess 132 (see FIG. 1). In this embodiment, the second protection layer 150a is in direct contact with the sidewall of the semiconductor substrate 110, the lateral surface of the bonding adhesive 120, the sidewall of the support element 130, the sidewall of the light-transmitting sheet 160a, and the top surface of the light-transmitting sheet 160a. In other embodiments, the top surface of the light-transmitting sheet 160a has no second protection layer 150a as deemed necessary by design.

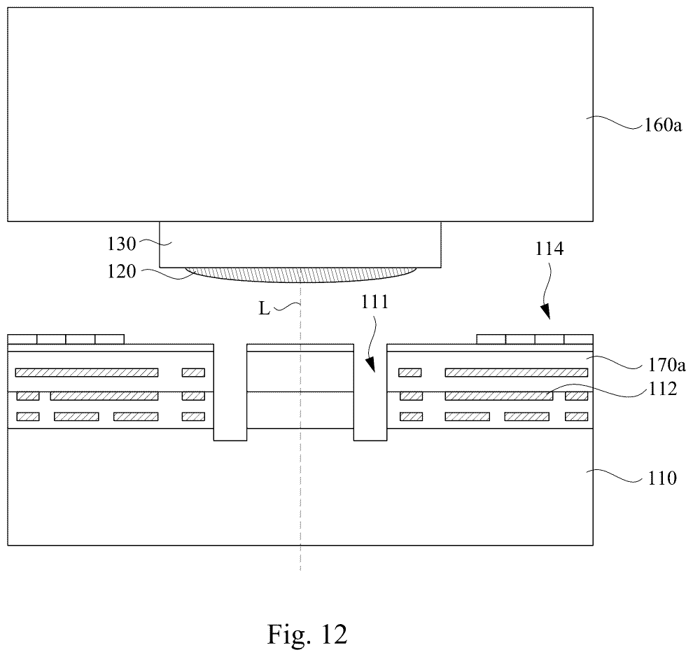

FIGS. 12 to 16 are cross-sectional views at intermediate stages of the manufacturing method of the chip package 100a of FIG. 11. As shown in FIG. 12, the bonding adhesive 120 is used to bond the support element 130 to the top surface of the semiconductor substrate 110, such that the bonding adhesive 120 is located in the groove 111, and the support element 130 covers the bonding adhesive 120. The difference between this embodiment and the embodiment of FIGS. 2 to 4 is that the thickness of the light-transmitting sheet 160a is greater than the thickness of the light-transmitting sheet 160, and this embodiment has sufficient supporting strength without using the carrier 210.

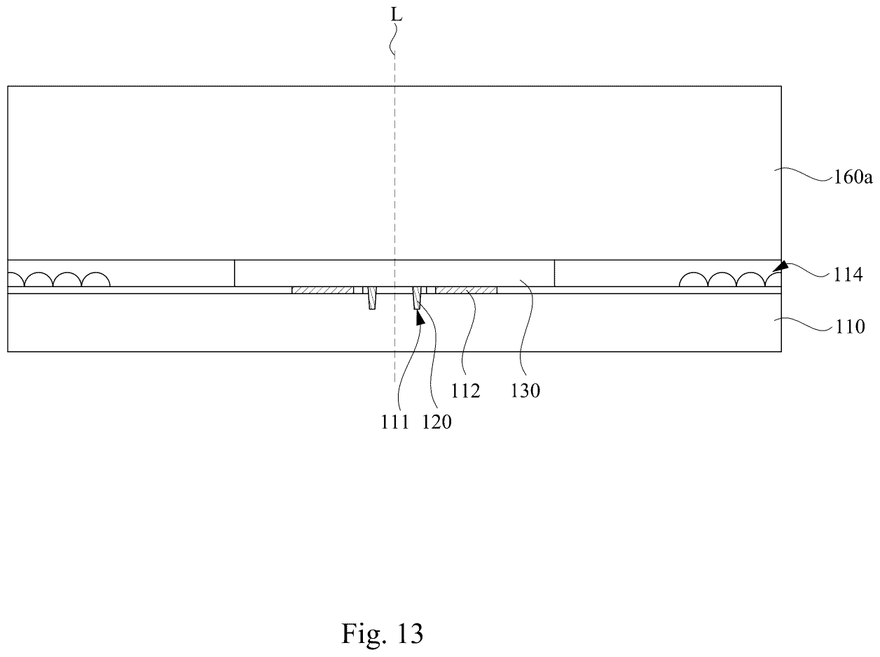

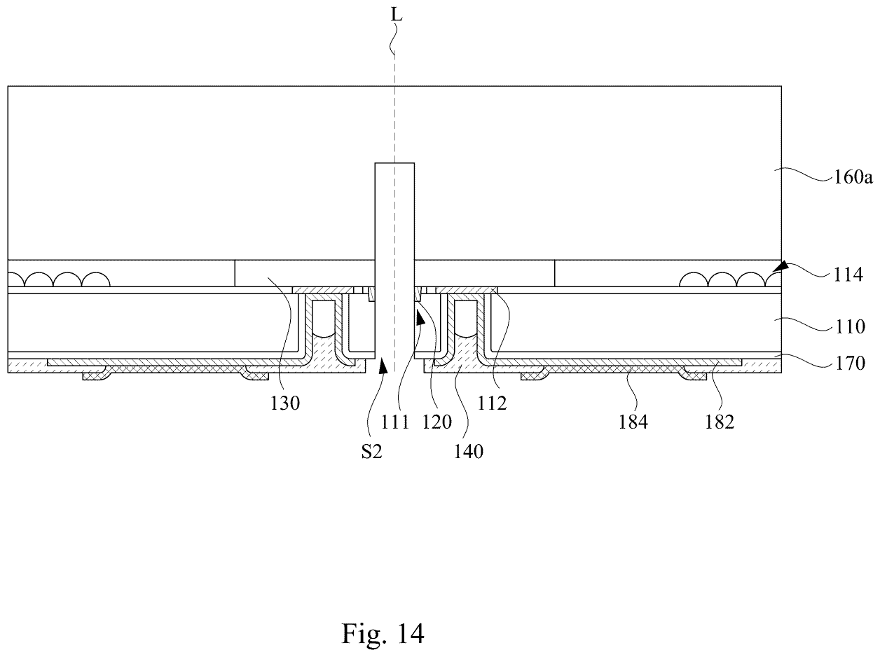

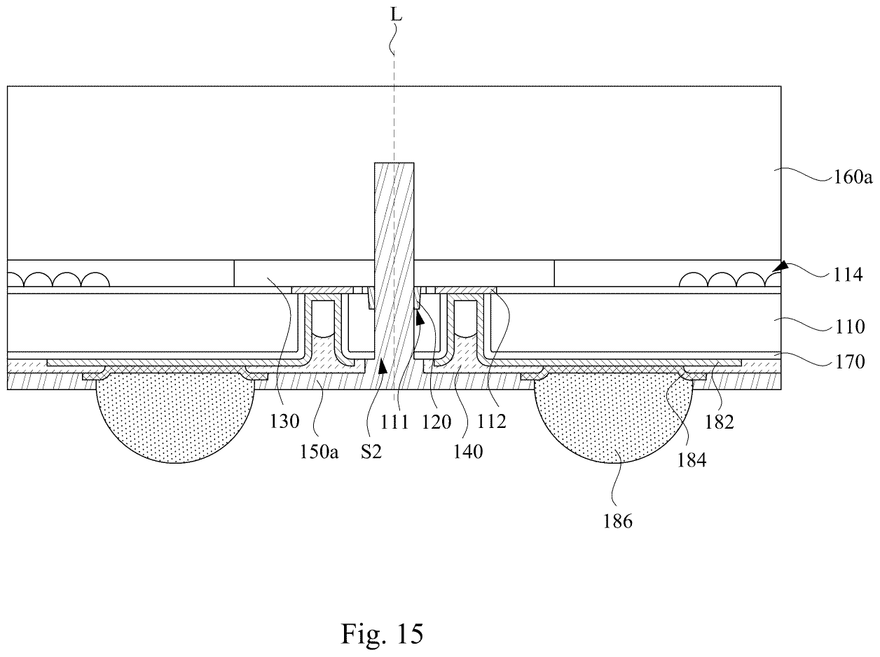

As show in FIG. 13, after the support element 130 is bonded to the semiconductor substrate 110, a grinding treatment may be performed on the bottom surface of the semiconductor substrate 110 to decrease the thickness of the semiconductor substrate 110. The steps after FIG. 13 and before FIG. 14 are the same as the aforementioned steps of FIG. 6 to FIG. 7, not be repeatedly described. As shown in FIG. 14, after the formation of the under bump metal 184, a scribe line S2 is formed in the semiconductor substrate 110 and the support element 130. In this step, the scribe line S2 extends into the light-transmitting sheet 160a. As shown in FIG. 15, thereafter, the second protection layer 150a is formed in the scribe line S2 and on the first protection layer 140, such that the second protection layer 150a covers the first protection layer 140, the sidewall of the semiconductor substrate 110, and the lateral surface of the bonding adhesive 120. In this embodiment, the second protection layer 150a extends into the light-transmitting sheet 160a.

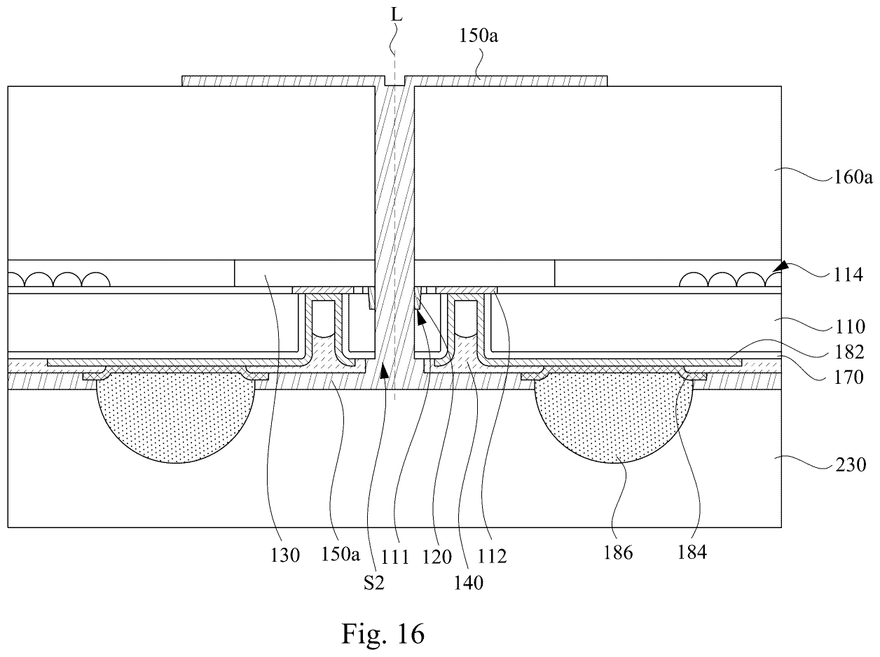

As shown in FIG. 16, thereafter, the structure of FIG. 15 is bonded to an adhesive tape 230, and then grinding the top surface of the light-transmitting sheet 160a is performed to the expose a portion of the second protection layer 150a. In other words, the light-transmitting sheet 160a is thinned to expose the top portion of the second protection layer 150a. Thereafter, another second protection layer 150a can be formed on the top surface of the light-transmitting sheet 160a by spin coating or screen printing, and the second protection layer 150a on the top surface of the light-transmitting sheet 160a extends to the exposed portion of the second protection layer 150a in the scribe line S2. Moreover, the second protection layer 150a on the top surface of the light-transmitting sheet 160a does not overlap the sensing area 114 of the semiconductor substrate 110 in a vertical direction, which allows the sensing area 114 to receive light.

In the following steps, the adhesive tape 230 can be removed, and the second protection layer 150a is cut along the scribe line S2 (i.e., the position of the dashed line L), and thus the chip package 100a of FIG. 11 is obtained.

According to the aforementioned chip package and its manufacturing method, it is beneficial for the designer to adjust the thickness ratio of the light-transmitting sheet to the semiconductor substrate. For example, the ratio of the thickness of the light-transmitting sheet to the thickness of the semiconductor substrate may be in a range from 0.75 to 2, thereby increasing flexibility for design.

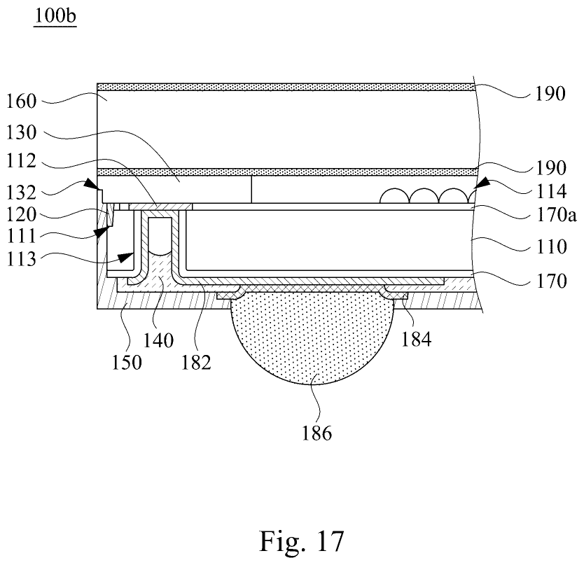

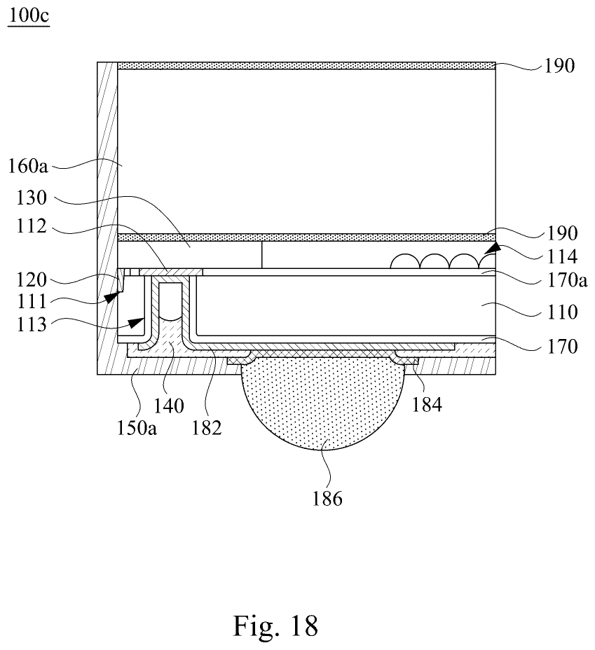

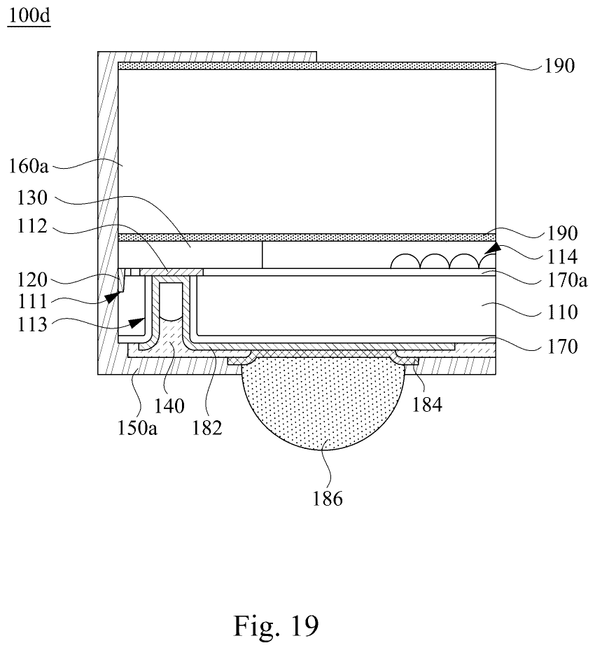

FIGS. 17 to 19 are cross-sectional views of chip packages 100b, 100c, and 100d according to other embodiments of the present disclosure. The difference between the embodiment of FIG. 17 and the embodiment of FIG. 1 is that the light-transmitting sheet 160 of the chip package 100b further includes two anti-reflective layers 190 that are respectively located on the top surface and the bottom surface of the light-transmitting sheet 160. As a result, the light-transmitting sheet 160 having the two anti-reflective layers 190 is a double layer anti-reflective glass. The anti-reflective layer 190 may be formed on the light-transmitting sheet 160 by coating, and can improve sensing performance by reducing light loss due to reflection, such as quantum efficiency and signal to noise ratio. The difference between the embodiment of FIG. 18 and the embodiment of FIG. 11 is that the light-transmitting sheet 160a of the chip package 100c further includes the two anti-reflective layers 190 that are respectively located on the top surface and the bottom surface of the light-transmitting sheet 160a, and the second protection layer 150a does not extend to the anti-reflective layer 190 on the top surface of the light-transmitting sheet 160a. The difference between the embodiment of FIG. 19 and the embodiment of FIG. 18 is that the second protection layer 150a of the chip package 100d extends to the anti-reflective layer 190 on the top surface of the light-transmitting sheet 160a.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A chip package, comprising:
a semiconductor substrate, wherein a top surface of the semiconductor substrate has a conductive pad and a sensing area, and a corner of the top surface has a groove;
a bonding adhesive located in the groove;
a support element covering the bonding adhesive and the conductive pad and surrounding the sensing area;
a first protection layer located on a bottom surface of the semiconductor substrate; and
a second protection layer covering the first protection layer, a sidewall of the semiconductor substrate, and a lateral surface of the bonding adhesive.

2. The chip package of claim 1, wherein a corner of a bottom surface of the support element has a recess, and the second protection layer extends into the recess.

3. The chip package of claim 1, further comprising:
a light-transmitting sheet located on the support element and above the sensing area.

4. The chip package of claim 3, wherein the second protection layer further covers a sidewall of the support element, a sidewall of the light-transmitting sheet, and a top surface of the light-transmitting sheet.

5. The chip package of claim 4, wherein the second protection layer is in direct contact with the sidewall of the semiconductor substrate, the lateral surface of the bonding adhesive, the sidewall of the support element, the sidewall of the light-transmitting sheet, and the top surface of the light-transmitting sheet.

6. The chip package of claim 3, wherein the light-transmitting sheet further comprises:
two anti-reflective layers respectively located on a top surface and a bottom surface of the light-transmitting sheet.

7. The chip package of claim 6, wherein the second protection layer extends to the anti-reflective layer on the top surface of the light-transmitting sheet.

8. The chip package of claim 1, wherein the second protection layer is in direct contact with the sidewall of the semiconductor substrate, the lateral surface of the bonding adhesive, and the support element.

9. The chip package of claim 1, wherein a material of the first protection layer is different from a material of the second protection layer, and a color of the first protection layer is different from a color of the second protection layer.

10. The chip package of claim 1, wherein the semiconductor substrate has a through hole, the conductive pad is located in the through hole, and the chip package further comprises:
an isolation layer located on a wall surface of the through hole and the bottom surface of the semiconductor substrate;
a redistribution layer located on the conductive pad and the isolation layer; and
an under bump metal located on the redistribution layer and the first protection layer.

11. The chip package of claim 10, wherein a material of the redistribution layer is copper, and a material of the under bump metal comprises copper, nickel, and gold.

12. The chip package of claim 10, wherein a portion of the under bump metal is located between the first protection layer and the second protection layer.

13. The chip package of claim 10, further comprising:
a conductive structure located on the under bump metal and surrounded by the second protection layer.

14. A manufacturing method of a chip package, comprising:
forming a groove in a top surface of a semiconductor substrate, wherein the top surface of the semiconductor substrate has a conductive pad and a sensing area;
using a bonding adhesive to adhere a support element to the top surface of the semiconductor substrate, wherein the bonding adhesive is located in the groove, and the support element covers the bonding adhesive and surrounds the sensing area;
forming a first protection layer on a bottom surface of the semiconductor substrate;
forming a scribe line in the semiconductor substrate and the support element, wherein the bonding adhesive is exposed through the scribe line; and
forming a second protection layer in the scribe line and on the first protection layer such that the second protection layer covers the first protection layer, a sidewall of the semiconductor substrate, and a lateral surface of the bonding adhesive.

15. The manufacturing method of the chip package of claim 14, wherein the groove of the semiconductor substrate is formed by laser grooving.

16. The manufacturing method of the chip package of claim 14, wherein forming the scribe line in the semiconductor substrate and the support element is performed such that a corner of a bottom surface of the support element has a recess.

17. The manufacturing method of the chip package of claim 16, wherein forming the second protection layer in the scribe line and on the first protection layer is performed such the second protection layer extends into the recess of the support element.

18. The manufacturing method of the chip package of claim 14, further comprising:
disposing the support element on a bottom surface of a light-transmitting sheet.

19. The manufacturing method of the chip package of claim 18, wherein a top surface of the light-transmitting sheet is bonded to a carrier, and the manufacturing method of the chip package further comprises:
cutting the second protection layer along the scribe line.

20. The manufacturing method of the chip package of claim 18, wherein forming the scribe line in the semiconductor substrate and the support element is performed such that the scribe line extends into the light-transmitting sheet.

21. The manufacturing method of the chip package of claim 20, wherein forming the second protection layer in the scribe line and on the first protection layer is performed such that the second protection layer extends into the light-transmitting sheet.

22. The manufacturing method of the chip package of claim 21, further comprising:
grinding a top surface of the light-transmitting sheet to expose a portion of the second protection layer; and
forming another second protection layer on the top surface of the light-transmitting sheet and extending to said portion of the second protection layer.
